(19) United States
(12) Patent Application Publication
(10) Pub. No.: US 2008/0094118 A1
(43) Pub. Date: Apr. 24, 2008

(54) OUTPUT INTERFACING DEVICE COMPENSATED IN LOAD AND CORRESPONDING ELECTRONIC CIRCUIT

(75) Inventors: Abdellatif Bendraoui, Saint-Julien de Concelles (FR); Joel Chatal, Carquefou (FR); Stanislas Gibet, Carquefou (FR)

Correspondence Address: WESTMAN CHAMPLIN & KELLY, P.A., SUITE 1400, 900 SECOND AVENUE SOUTH, MINNEAPOLIS, MN, 55402-3319, US

(73) Assignee: Atmel Nantes SA, Nantes Cedex (FR)

(21) Appl. No.: 11/875,234

(22) Filed: Oct. 19, 2007

(30) Foreign Application Priority Data
Oct. 20, 2006 (FR) 06/09246

(51) Int. Cl. H03K 5/12

(52) U.S. Cl. 327/170

(57) ABSTRACT

An output interfacing device is provided, which receives at its input an input signal and provides at its output, an output signal to an external load. The output interfacing device invertes the effect of the capacitance of the external load on the slew rate of the output signal.

### CROSS-REFERENCE TO RELATED APPLICATION

None.

### FIELD OF THE DISCLOSURE

The field of the disclosure is that of integrated electronic circuits and more particularly output buffers (also called hereunder output interfacing devices).

Such interfacing devices are well known in the prior art. They are generally positioned at the periphery of an integrated circuit and are used to interface electric signals from the core of the circuit to outside the circuit.

More precisely, the disclosure relates to the control of the slew rate of the output signal of such interfacing devices.

### BACKGROUND

Below will be covered the disadvantages of the prior art via the specific case of a NMOS type output buffer (which is to say an output buffer whose output transistor is of the NMOS type).

In all of the figures of this document, identical elements or signals are designated by a same alphanumerical reference.

Currently, more and more electronic equipment is equipped with dozens or even hundreds of very rapid output buffers.

In relation to FIG. 1. the electrical diagram of a classic output interfacing device is presented, reference 100 (also called hereunder first classic interfacing device).

For reasons of simplification of the description, the rest of the document will simply describe the specific case of interfacing devices operating with power supply voltages of between 0V and 5V. Those skilled in the art will extend without difficulty this lesson to any types of voltage designed to power an integrated electronic circuit.

The output interfacing device 100 receives on an input 1 an input signal SIN and supplies at an output 2 an output signal SOUT.

This output interfacing device 100 comprises a control stage E1 comprising an inverter INV, and an output stage E2, comprising an output transistor TN2.

More precisely, the inverter INV receives on an input 11 the input signal SIN and supplies a command signal SCOM to a mid point A. This inverter INV comprises a transistor TP1 whose source SP1 is connected to the power supply VCC of the circuit (also called high logic level in the rest of the description) and whose drain DP1 is connected to the mid point A, and a transistor TN1. whose source SN1 is connected to reference potential VSS (also called low logic level in the rest of the description) and whose drain DN1 is connected to the drain DP1 of the transistor TP1. The transistors TP1 and TN1 receive on their gate GP1 and GN1, the input signal SIN.

Consequently, when the input signal SIN is substantially equal to the reference potential VSS, the transistor TP1 is conductive and the transistor TN1 is non conductive. The inverter INV then delivers a command signal SCOM, which is substantially equal to the power supply VCC, to the mid point A.

However, when the input signal SIN is substantially equal to the power supply VCC, the transistor TN1 is made conductive and the transistor TP1 non conductive. The inverter then INV delivers a command signal SCOM, which is substantially equal to the reference potential VSS, to the mid point A.

The output transistor TN2, whose source SN2 is connected to the reference potential VSS and whose drain DN2 is connected to the output 2, forms a switch commanded by the command signal SCOM (applied to the gate GN2).

Hereunder in reference to FIG. 1 is described the operation of the output interfacing device 100 of the prior art. This device comprises at its output a capacitive load C1 (situated between the output 2 and the reference potential VSS), at the terminals of which may be measured the slew rate of the output signal SOUT.

When the input signal SIN passes from the reference potential VSS to a voltage (substantially equal to the power supply VCC) of 4V, the command signal SCOM (delivered to the mid point A) then substantially becomes equal to the reference potential VSS, which is to say 0V. The output transistor TN2, whose gate GN2 receives the command signal SCOM, is then placed in a non conductive state (switch open).

In return, when the input signal SIN passes from the power supply VCC to the reference potential VSS, which is to say 0V, the command signal SCOM (delivered to the mid point A) then substantially becomes equal to the power supply VCC, which is to say 5V. The output transistor TN2, whose gate GN2 receives the command signal SCOM, is then placed in a conductive state (switch closed), in which it delivers a drain current Id2 to the output 2. The overall current Id2 loads the output capacitance C1. This loading is carried out at constant current and causes very rapid switching on the output 2 (in other terms, the output signal SOUT has a high slew rate).

In relation to FIG. 2 are presented the dynamic performances (time for the output signal SOUT to descend, measured at the terminals of the capacity C1) of the output interfacing device 100 of FIG. 1 in response to an input signal SIN in the form of a conductive voltage scale for a voltage substantially equal to the power supply VCC (4V) to VSS (0V).

More precisely, FIG. 2 shows three curves references 201 to 203 illustrating the voltage (in volts) of the output signal SOUT as a function of time t expressed in microseconds (μs) for three capacitance values C1. Consequently, the curve with the reference 201 corresponds to a capacitance of 50 pF, the curve with the reference 202 corresponds to a capacitance of 200 pF and the curve with the reference 203 corresponds to a capacitance of 500 pF.

As shown by FIG. 2, the rapidity of the output interfacing device 100 of the prior art decreases strongly when the output capacitive load increases. In fact, if the curve 201 is compared with the curve 203, it may be seen that; with a capacitance of 500 pF at the output of the device, it takes approximately ten times longer to pass from VCC (high logic state) to VSS (low logic state).

The major disadvantage of this first known interfacing device lies therefore in the fact that it has transition times (which is to say the time required to pass from one logic state to the complementary logic state) that are relatively long, especially for high capacitive charges.

To overcome this problem of the drop in dynamic performances, it is traditionally envisaged to introduce a slew rate control resistor into the previously mentioned output interfacing device 100.

As shown in FIG. 3, in the output classic interfacing device, reference 200 (also called hereunder second classic interfacing device), the control resistor RSL is mounted in series with the transistor TP1. More precisely, the control resistor RSL comprises a first end 301 that is connected to the drain DP1 of the transistor TP1 and a second end 302 that is connected to the mid point A. This control resistor RSL permits the increase in the gate voltage VGN2 of the output transistor TN2 to be slowed down. This solution thus permits the slew rate of the output signal SOUT to be limited.

In fact, when the input signal SIN passes from VCC to VSS, the gate capacitance (not shown) of the output transistor TN2 is loaded via the command signal SCOM, the effect of which is to load the capacitance C1. The consequence of this is to delay the command from the output transistor TN2, and thus delay the generation of the current Id2 on the output 2.

Now in relation to FIG. 4 are presented the dynamic performances (time for the output signal SOUT to descend, measured at the terminals of the capacitance C1) of the output interfacing device 200 of FIG. 3 in response to an input signal SIN in the form of a conductive voltage scale for a voltage substantially equal to the power supply VCC (4V) to VSS (0V).

More precisely, FIG. 4 shows three curves references 401 to 403 showing the voltage (in volts) of the output signal SOUT as a function of time t expressed in microseconds (μs) for three capacitance values C1. Consequently, the curve with the reference 401 corresponds to a capacitance of 50 pF, the curve with the reference 402 corresponds to a capacitance of 200 pF and the curve with the reference 403 corresponds to a capacitance of 500 pF.

As shown in FIG. 4, the rapidity of the output interfacing device 200 of the prior art decreases slightly when the output capacitive load increases. In fact, if the curve 401 is compared with the curve 403, it may be seen that; with a capacitance of 500 pF at the output of the device, it takes approximately three times longer to pass from VCC to VSS.

Even though this solution of the prior art represents significant progress in the mechanism for reducing the impact of the capacitive load on the dynamic performances of the interfacing device, the second known technique still has the disadvantage of being sensitive to high capacitive loads, in other terms, the more that the output capacitance increases, the more that the transition time is slowed down.

### SUMMARY

An output interfacing device is provided, which receives at its input an input signal and provides at its output, to an external load, an output signal.

In one example, the device includes means of inverting the effect of the capacitance of the external load capacitance on the slew rate of the output signal. The inverting means comprising means of increasing the slew rate of the output signal. The device comprises means of initialising said increasing means, allowing said increasing means to be initialised every time that said input signal switches between a first level and a second level.

Consequently, the disclosure is based, for example, on a novel and inventive approach to the control of the slew rate of the output signal of an output interfacing device. In fact, the disclosure proposes the use of inverting means to increase the rapidity of the device when the output capacitive load increases. In other terms, the more that the capacitive load increases, the more that the slew rate of the output signal increases, in response to a voltage scale applied to the input of the device.

Said device comprises switching means for said output signal. In one advantageous aspect of the disclosure, said means for inverting the effect of the capacitance of the output load on the slew rate of the output signal comprise:
means of decreasing the slew rate of the output signal, allowing the command of said switching means to be delayed, as long as a predetermined command criterion has not been verified.

Consequently, the disclosure proposes the association of means of decreasing and increasing the slew rate of the output signal. These means are activated successively, which is to say firstly the means of decreasing are activated as long as a predetermined command criterion has not been verified (for example if a voltage threshold has not been reached), then when the criterion is verified, the means of increasing are activated.

Said device comprises first and second transistors mounted with common gate and drain, so as to form a first inverter. In one example, said means of decreasing the slew rate of the output signal comprise at least one resistive element mounted between the first transistor and the second transistor.

Advantageously, said means of increasing the slew rate of the output signal comprise feed back means for the output of said switching means to the input of said switching means.

It is important to note that the feed back means create a counter-reaction in the circuit which accelerates the switching dynamic of the circuit.

Preferably, said feed back means comprise at least one capacitive element.

Advantageously, the device comprises command means for said feed back means, permitting said feed back means to be blocked as long as said predetermined command criterion has not been verified.

Preferably, said command means comprise:
a third transistor forming a switch and mounted between said feed back means and said switching means; and
a second inverter acting on third transistor so that:

as long as said predetermined command criterion has not been verified, then said third transistor is placed in a non conductive state.

Consequently, as soon as the inverter (reference INV2 in FIG. 5) reaches its threshold (for example 1.5V), the switch closes (the third transistor TN3 is conductive) and the drain potential of the output transistor (reference TN2 in FIG. 5) is brought onto its gate.

In one advantageous aspect of the disclosure, the device further comprises means of initialising said feed back means, permitting the initialisation of said feed back means each time that said input signal switches between a first level and a second level.

Consequently, the initialisation means permit the capacitive element to be discharged (used for the feed back) each time that the input signal is switched (for example when the input signal switches from VCC to VSS).

Preferably, said initialisation means comprise a fourth PMOS type transistor mounted with common source and drain with a fifth NMOS type transistor.

The disclosure also relates to an electronic circuit comprising an output interfacing device such as that described above.

Other characteristics and advantages will become clearer after reading the following description, provided simply by way of one or more illustrative and non restrictive examples, and the appended drawings.

### BRIEF DESCRIPTION OF THE DRAWINGS

FIG. 1 already commented on in relation to the prior art, shows an electrical diagram of a first classic interfacing device;

FIG. 2, also commented on in relation to the prior art, shows the performances of the interfacing device of FIG. 1;

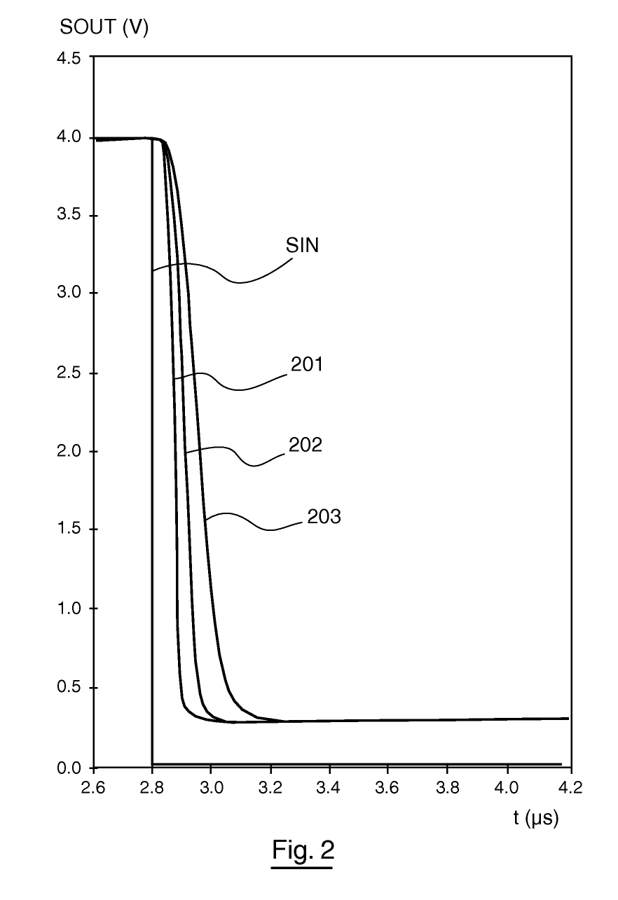

FIG. 3, already commented on in relation to the prior art, shows an electrical diagram of a second classic interfacing device;

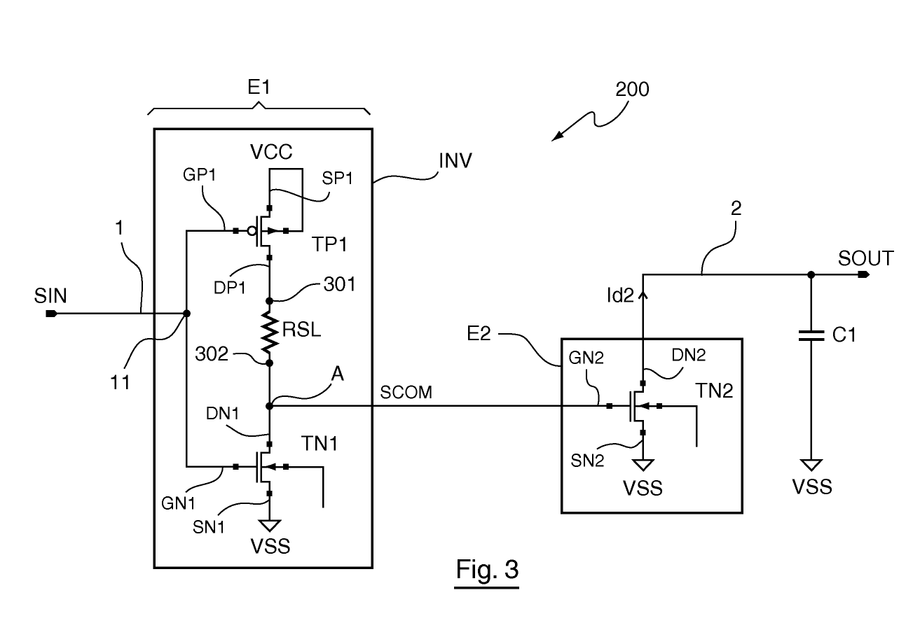

FIG. 4, also commented on in relation to the prior art, shows the performances of the interfacing device of FIG. 3;

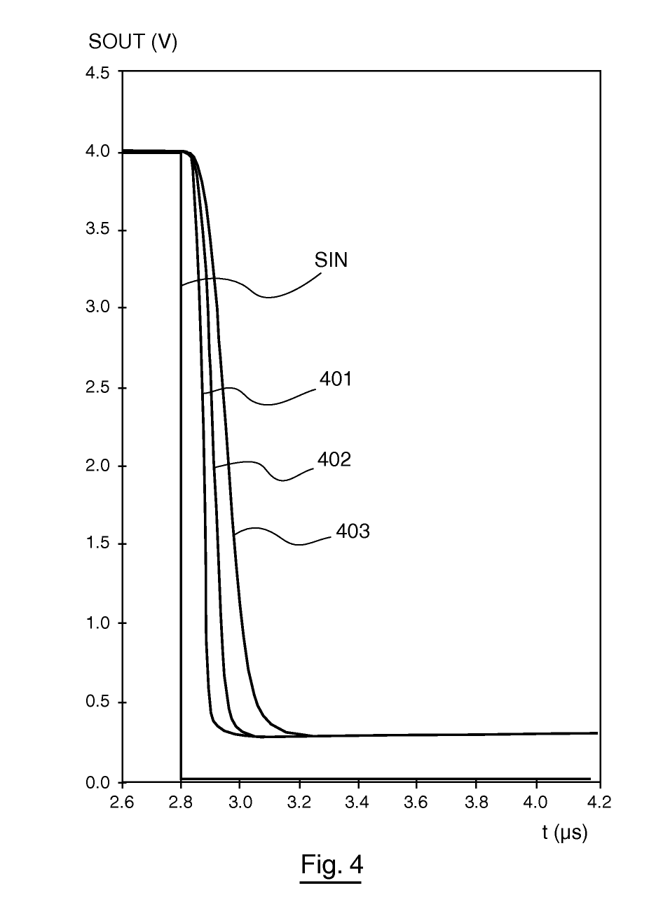

FIG. 5 shows the electrical diagram of an interfacing device in one example of the present disclosure; and

FIG. 6 shows the performances of the interfacing device shown in FIG. 5, for three values of output capacitance.

### DETAILED DESCRIPTION OF ILLUSTRATIVE EMBODIMENTS

The general principle of the disclosure is based, for example, on the reduction and the increase of the slew rate of the output signal of an interfacing device.

Simplification of the description, the rest of the document will simply describe the specific case of a NMOS type output buffer. Those skilled in the art will extend without difficulty this lesson to any types of output buffers, especially de PMOS and “push-pull” type output buffers.

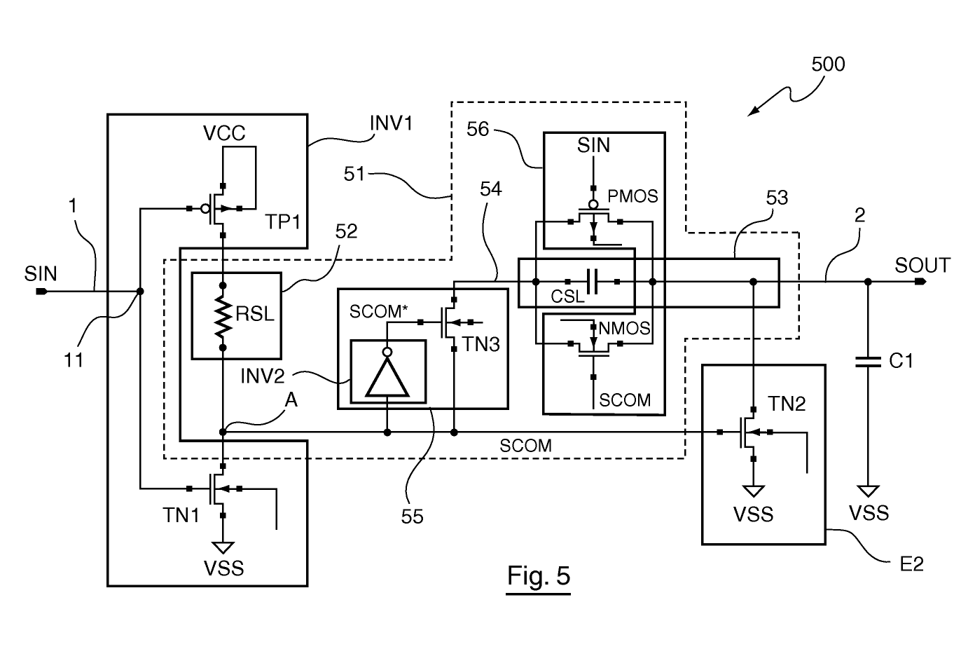

In relation to FIG. 5 an output interfacing device 500 will be described in one example of the disclosure.

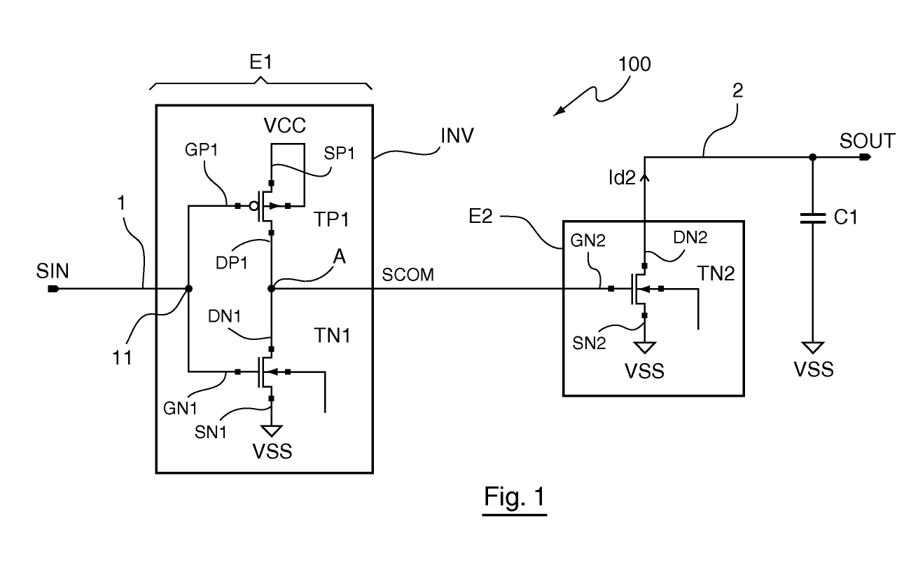

In this example, the output interfacing device 500 comprises:
a first inverter INV1 corresponding to the command stage E1 described in relation to FIG. 1;
an output stage E2 classic in itself, comprising an output transistor TN2: and
inverting means 51 specific to the present disclosure.

For reasons of clarity, the detailed architecture and the operation of the first inverter INV1 are not described again below.

By way of reminder, this first inverter INV1 is formed by a first transistor TP1 and a second transistor TN1. mounted with common gate and drain.

The output interfacing device 500 comprises an input 1 to which is applied an input SIN and an output 2 signal delivering an output signal SOUT to an external load C1 (which is for example a capacitance of 50 pF).

As shown in FIG. 5, the means for inverting 51 the effect of the external load capacitance on the slew rate of the output signal comprise:
means of decreasing 52 the slew rate of the output signal comprising a control resistor RSL mounted between the drain of the first transistor TP1 and the drain of the second transistor TN1; and
means of increasing 53 the slew rate of the output signal comprising a feed back 54 of the drain of the output transistor TN2 to its gate.

As may be seen below, the feed back 54 creates a feed back loop, which accelerates the switching dynamic of the device.

In one example, the feed back is carried out via a control capacitance CSL. Advantageously, initialisation means 56 are provided to discharge the control capacity CSL. The initialisation means 56 comprise a fourth PMOS type transistor mounted with common source and drain with a fifth NMOS type transistor. The fourth PMOS transistor is commanded by the input signal SIN (which is applied to the gate of the transistor), and the fifth transistor NMOS is commanded by the command signal SCOM delivered by the first inverter INV1. Consequently, at each switching of the input signal from VCC to VSS, the fourth PMOS and fifth NMOS transistors are made conductive, which has the effect of short circuiting the control capacitance CSL and thus of discharging it.

In this example, the output interfacing device 500 further comprises command means 55 permitting the feed back to be authorised or not.

As shown by FIG. 5, the command means 55 comprise:
a second inverter INV2 receiving at its input the command signal SCOM and providing at its output an inverted command signal SCOM*; and
a third transistor TN3, whose source is connected to the gate of the output transistor TN2 and whose drain is connected to one end of the control capacitance CSL, forming a switch commanded by the inverted command signal SCOM* (applied to the gate of the transistor TN3).

Hereunder in reference to FIG. 5 is described the operation of the output interfacing device 500, for the switching of the input signal SIN from VCC to VSS. By way of example, it is considered that the second inverter INV2 switches, which is to say it delivers an inverted command signal SCOM substantially equal to VCC, when the input signal SIN is greater than 1.5V.

When the input signal SIN is greater than or equal to VSS and less than or equal to 1.5V, the capacitance of the gate (not shown) of the output transistor TN2 is loaded via the command signal SCOM. The increase in voltage of the command signal SCOM is controlled (which is to say delayed) by the control resistor RSL. The consequence of this is to delay the command of the output transistor TN2, and therefore to slow down the switching speed of the device. It is important to note that, in this case, the second inverter INV2 delivers an inverted command signal SCOM* substantially equal to VSS. The third transistor TN3 is therefore made non conductive (switch open), which has the effect of deactivating the feed back loop. It may also be noted that the control resistor RSL improves the immunity of the device to interference and/or electromagnetic interference.

In return, when the input signal SIN is greater than 1.5V and less than or equal to VCC, the second inverter INV2 delivers an inverted command signal SCOM* substantially equal to VCC, the third transistor TN3 is therefore made conductive (switch closed) and the feed back loop activated. The gate capacitance (not shown) of the output transistor TN2 is then loaded via the output signal SOUT (which is supplied by the control capacitance CSL). The consequence of this is to accelerate the command of the output transistor TN2, and therefore to increase the switching speed of the device.

The addition of the control resistor RSL with the feed back loop (control capacitance CSL) permits the effect of the external load capacitance C1 on the slew rate) of the output signal SOUT to be inverted.

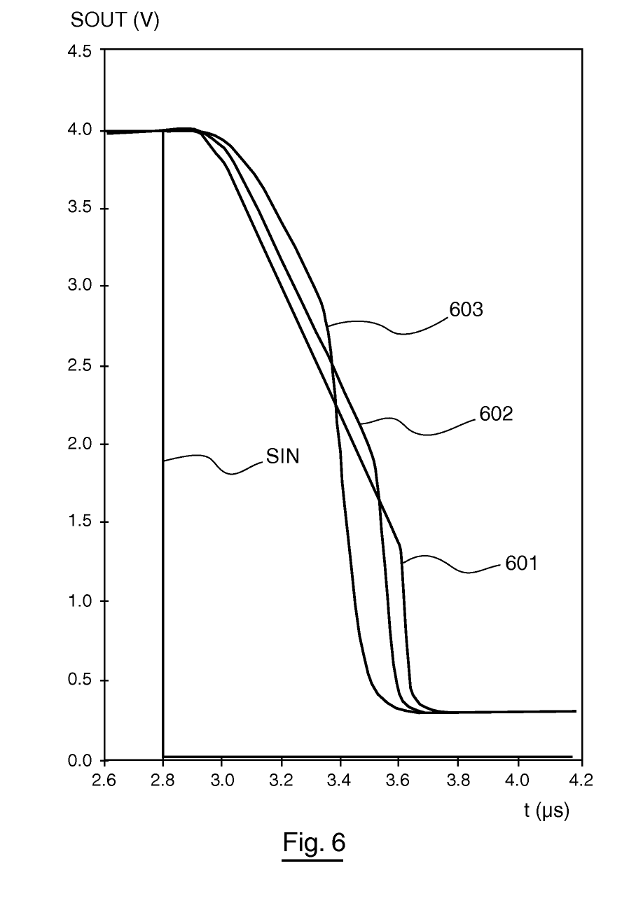

Now in relation to FIG. 6 are presented the dynamic performances (falling time for the output signal SOUT measured at the terminals of the capacitance C1) of the output interfacing device 500 (FIG. 5) in response to an input signal SIN in the form of a conductive voltage scale of a voltage substantially equal to the power supply VCC (4V) to VSS (0V).

More precisely, FIG. 6 shows three curves references 601 to 603 showing the voltage (in Volts) of the output signal SOUT as a function of temps t expressed in microseconds (μs) for three values of capacitance C1. Consequently, the curve with the reference 601 corresponds to a capacitance of 50 pF, the curve with the reference 602 corresponds to a capacitance of 200 pF and the curve with the reference 603 corresponds to a capacitance of 500 pF.

As shown in FIG. 6, the rapidity of the output interfacing device 500 increases when the output capacitive load increases. In fact, if the curve 601 is compared with the curve 603, it may be seen that; with a capacitance of 500 pF at the output of the device, it takes approximately twice less time to pass from VCC to VSS.

An example of the disclosure provides a technique, which permits simple and efficient control of the slew rate of the output signal of an output interfacing device.

An example of the disclosure provides a system, which permits the slew rate of the output signal to be accelerated, when the capacitance of the load at the output of the device increases.

It should be noted that the formulation of this advantage is, in itself, novel and inventive as those skilled in the field of output interfacing devices have not yet envisaged obtaining a slew rate of the output signal that is increasingly higher for a capacitive load that is increasingly higher.

An example of the disclosure provides a system, which generates reduced interference with respect to the classic output interfacing devices.

An example of the disclosure provides a system, which is simple and inexpensive to make.

Although the present disclosure has been described with reference to one or more examples, workers skilled in the art will recognize that changes may be made in form and detail without departing from the spirit and scope of the disclosure and/or the appended claims.

What is claimed is:

1. Output interfacing device receiving at its input an input signal and providing at its output, to an external load, an output signal, wherein the device comprises:
means of inverting the effect of the capacitance of the external load on the slew rate of the output signal, said inverting means comprising means of increasing the slew rate of the output signal, and
means of initialising said increasing means, allowing said increasing means to be initialised every time that said input signal switches between a first level and a second level.

2. Output interfacing device according to claim 1, said device further comprising means of switching said output signal,
wherein said inverting means of the effect of the capacitance of the external load on the slew rate of the output signal comprise means of decreasing the slew rate of the output signal, allowing a command of said switching means to be delayed, as long as a predetermined command criterion has not been verified.

3. Output interfacing device according to claim 2, said device comprising first and second transistors mounted with common gate and drain, so as to form a first inverter,
wherein said means of decreasing the slew rate of the output signal comprise at least one resistive element mounted between the first transistor and the second transistor.

4. Output interfacing device according to any of claim 1, wherein said means of increasing the slew rate of the output signal comprise feed back means of the output of said switching means on the input of said switching means.

5. Output interfacing device according to claim 4, wherein said feed back means comprise at least one capacitive element.

6. Output interfacing device according to any of claim 1, wherein the device comprises command means of said feed back means, for allowing said feed back means to be blocked as long as said predetermined command criterion has not been verified.

7. Output interfacing device according to claim 6, wherein said command means comprise:
a third transistor forming a switch and mounted between said feed back means and said switching means; and
a second inverter acting on said third transistor so that:
as long as said predetermined command criterion has not been verified, then said third transistor is placed in a non conductive state.

8. Output interfacing device according to claim 1, wherein said initialisation means comprise a fourth PMOS type transistor mounted with common source and drain with a fifth NMOS type transistor.

9. Electronic circuit wherein the circuit comprises an output interfacing device according to claim 1.

10. Output interfacing device comprising:
an input receiving an input signal;
an output providing an output signal to an external load;
first and second transistors mounted with common gate and drain, so as to form a first inverter, and at least one resistive element mounted between the first transistor and the second transistor;
a first switch, which switches the output signal on the output;
feed back from the output of the switch to an input of the first switch; and
a circuit, which blocks the feed back as long as a predetermined command criterion for the first switch has not been verified.

11. Output interfacing device according to claim 10, wherein said feed back comprises at least one capacitive element.

12. Output interfacing device according to claim 10, wherein said circuit, which blocks the feed back, comprises:
a third transistor forming a second switch and mounted between said feed back and said first switch; and
a second inverter acting on said third transistor so that:
as long as said predetermined command criterion has not been verified, then said third transistor is placed in a non conductive state.

13. Output interfacing device according to claim 10, and further comprising a fourth PMOS type transistor mounted with common source and drain with a fifth NMOS type transistor, the common source and drain being coupled to the output.

14. An electronic circuit comprising an output interfacing device according to claim 10.

15. A method comprising:
receiving an input signal at an input of an output interfacing device providing at its output an output signal to an external load;
inverting an effect of a capacitance of the external load on the slew rate of the output signal, comprising increasing the slew rate of the output signal, and
initialising the slew rate of the output signal every time that said input signal switches between a first level and a second level.
